(19) United States
(12) Patent Application Publication
(10) Pub. No.: US 2024/0306474 A1
(43) Pub. Date: Sep. 12, 2024

(54) COVER WINDOW, METHOD OF MANUFACTURING THE SAME, AND DISPLAY DEVICE INCLUDING THE SAME

(71) Applicant: Samsung Display Co., LTD., Yongin-si (KR)

(72) Inventors: HYUNSEUNG SEO, Yongin-si (KR); Jinsu Nam, Yongin-si (KR); YONGKYU KANG, Yongin-si (KR); JIHYUN KO, Yongin-si (KR); Junho Lee, Yongin-si (KR)

(73) Assignee: Samsung Display Co., LTD., Yongin-si (KR)

(21) Appl. No.: 18/441,404

(22) Filed: Feb. 14, 2024

(30) Foreign Application Priority Data
Mar. 7, 2023 (KR) 10-2023-0029927

(51) Int. Cl. H10K 59/80; H10K 59/12; H10K 102/00

(52) U.S. Cl. CPC H10K 59/873; H10K 59/1201; H10K 2102/311

(57) ABSTRACT

A cover window includes a first area and a second area, a base layer disposed in the first area and the second area and having flexibility in the first area, and a functional layer disposed on at least one surface of the base layer and including: a first part disposed in the first area and including a first ion and a second part disposed in the second area and including a second ion different from the first ions.

### CROSS-REFERENCE TO RELATED APPLICATION(S)

This application claims priority to and benefits of Korean Patent Application No. 10-2023-0029927 under 35 U.S.C. § 119, filed on Mar. 7, 2023, in the Korean Intellectual Property Office (KIPO), the entire contents of which are incorporated herein by reference.

### BACKGROUND

### 1. Technical Field

Embodiments provide a chemically strengthened cover window, the method of manufacturing the cover window, and the display device including the cover window.

### 2. Description of the Related Art

As information technology develops, the importance of display devices, which are communication media between users and information, is being highlighted. Accordingly, the use of display devices such as a solution crystal display device, an organic light emitting display device, a plasma display device, and the like is increasing.

A display device includes a display panel and a cover window disposed on the display panel. The cover window has strength to protect the display panel.

### SUMMARY

Embodiments provide a cover window that prevents a damage caused by bending.

Embodiments provide a method for manufacturing the cover window.

Embodiments provide a display device including the cover window.

A cover window according to embodiments of the disclosure may include a first area and a second area disposed adjacent to the first area, a base layer disposed in the first area and the second area and having flexibility in the first area, and a functional layer disposed on at least one surface of the base layer and including a first part disposed in the first area and including a first ion and a second part disposed in the second area and including a second ion different from the first ion.

In an embodiment, an ionic radius of the second ion may be greater than an ionic radius of the first ion.

In an embodiment, the first part may include a first amount of the first ion, and the second part may include the first amount of the second ion.

In an embodiment, the first part may include a first amount of the first ion, the second part may include a second amount of the second ion, and the second amount may be greater than the first amount.

In an embodiment, the first part may have a first thickness in a thickness direction of the base layer, and the second part may have a second thickness greater than the first thickness in the thickness direction.

In an embodiment, a first compressive stress may be formed in the first part, a second compressive stress may be formed in the second part, and a maximum value of the second compressive stress may be greater than a maximum value of the first compressive stress.

In an embodiment, a same tensile stress may be formed in the first area and the second area of the base layer.

In an embodiment, a groove may be formed on an upper surface of the cover window in the first area.

In an embodiment, the cover window may include amorphous glass in the first area and crystalline glass in the second area.

In an embodiment, the functional layer may include a first functional layer disposed on a first surface of the base layer and a second functional layer disposed on a second surface opposite to the first surface of the base layer.

A method for manufacturing the cover window according to embodiments of the disclosure may include forming a base member including a glass substrate, applying a first coating solution including a first ion to at least one surface of the base member in a first area, the first area of the base member having flexibility, applying a second coating solution including a second ion different from the first ion to at least one surface of the base member in a second area disposed adjacent to the first area, heating the base member on which the first and second coating solutions are formed, and removing the first and second coating solutions.

In an embodiment, the first coating solution may have a first thickness in a thickness direction of the base member, and the second coating solution may have the first thickness in the thickness direction.

In an embodiment, the base member may further include the second ion, the first coating solution may further include the second ion, and the second coating solution may further include the first ion.

In an embodiment, a ratio of the first ion and the second ion in the first coating solution and a ratio of the first ion and the second ion in the second first coating solution may be different. The first coating solution may include a first amount of the first ion, the second coating solution may include a second amount of the first ion, and the second amount may be greater than the first amount.

In an embodiment, a ratio of the first ion and the second ion in the first coating solution and a ratio of the first ion and the second ion in the second first coating solution may be same. The first coating solution may include a first amount of the first ion, the second coating solution may include a second amount of the first ion, and the second amount may be greater than the first amount.

In an embodiment, the base member may further include a third ion different from the first and second ions, and an ionic radius of the second ion may be greater than an ionic radius of the first ion.

In an embodiment, the first coating solution may include a first amount of the first ion, and the second coating solution may include the first amount of the second ion.

In an embodiment, the forming of the base member may include forming a groove on an upper surface of the base member in the first area and crystallizing the glass substrate by heating the second area of the base member.

In an embodiment, the heating of the base member on which the first and second coating solutions are formed may include forming a cover window including a base layer in the first area and the second area, and a functional layer formed on at least one surface of the base layer. The functional layer may include a first part disposed in the first area and having a first thickness in a thickness direction of the base member, and a second part disposed in the second area and having a second thickness greater than the first thickness in the thickness direction.

A display device according to embodiments of the disclosure may include a display panel including a display area that displays an image and a non-display area disposed adjacent to the display area, and a cover window disposed on the display panel and including a first area and a second area disposed adjacent to the first area, a base layer disposed in the first area and the second area and having flexibility in the first area, and a functional layer disposed on at least one surface of the base layer and including a first part disposed in the first area and including a first ion and a second part disposed in the second area and including a second ion different from the first ion.

A display device according to embodiments of the disclosure may include a display panel and a cover window disposed on the display panel and including a first area having flexibility and a second area disposed adjacent to the first area. The cover window may include a base layer and a functional layer disposed on at least one surface of the base layer and formed through an ion exchange process. The functional layer may include a first part in the first area and including a first ion, and a second part in the second area and including a second ion having an ion radius greater than an ion radius of the first ion. In another embodiment, the functional layer may include a first part in the first area and including a first amount of a first ion, and a second part in the second area and including a second amount of the first ion, the second amount greater than the first amount. Accordingly, the strength of the functional layer of the cover window may be increased, and a damage caused by bending of the cover window may be prevented.

In the method for manufacturing a cover window according to the embodiments of the disclosure, after simultaneously applying coating solutions to the first area having flexibility and the second area disposed adjacent to the first area of a base member including a glass substrate, an ion exchange process may be simultaneously performed in the first and second areas by heating the base member to which the coating solutions are applied. Accordingly, the manufacturing process of the cover window may be simplified.

### BRIEF DESCRIPTION OF THE DRAWINGS

Illustrative, non-limiting embodiments will be more clearly understood from the following detailed description in conjunction with the accompanying drawings.

FIG. 1 is a perspective view of a display device according to an embodiment of the disclosure.

FIG. 2 is a plan view of a display panel included in the display device of FIG. 1.

FIG. 3 is a plan view of a cover window included in the display devicd of FIG. 1.

FIG. 4 is a schematic cross-sectional view of a part of the display panel of FIGS. 1 and 2.

FIG. 5 is a schematic cross-sectional view of the cover window of FIG. 3 taken along line I-I′.

FIG. 6 is a schematic cross-sectional view of areas AA, BB, and CC of FIG. 5 according to an embodiment.

FIG. 7 is a schematic cross-sectional view of areas AA, BB, and CC of FIG. 5 according to an embodiment.

FIG. 8 is a schematic diagram illustrating a dry ion exchange process.

FIGS. 9, 10, 11, and 12 are schematic cross-sectional views illustrating a method for manufacturing the cover window of FIG. 5.

FIG. 13 is a schematic cross-sectional view of a cover window according to another embodiment of the disclosure.

FIG. 14 is a schematic cross-sectional view of areas AA′, BB′, and CC′ of FIG. 13.

FIGS. 15, 16, 17, and 18 are schematic cross-sectional views illustrating a method for manufacturing the cover window of FIG. 13 according to an embodiment.

FIGS. 19 and 20 are schematic cross-sectional views illustrating a method for manufacturing the cover window of FIG. 13 according to an embodiment.

FIG. 21 is a schematic cross-sectional view of a cover window according to another embodiment of the disclosure.

FIG. 22 is a schematic cross-sectional view of areas AA″, BB″ and CC″ of FIG. 21 according to an embodiment.

FIG. 23 is a schematic cross-sectional view of areas AA″, BB″ and CC″ of FIG. 21 according to an embodiment.

FIG. 24 is a schematic cross-sectional view of areas AA″, BB″ and CC″ of FIG. 21 according to an embodiment.

### DETAILED DESCRIPTION OF THE EMBODIMENTS

Hereinafter, a cover window, a method for manufacturing the cover window, and a display device including the cover window according to embodiments of the disclosure will be explained in detail with reference to the accompanying drawings. The same reference numerals are used for the same components in the drawings, and redundant descriptions of the same components will be omitted.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Further, the first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

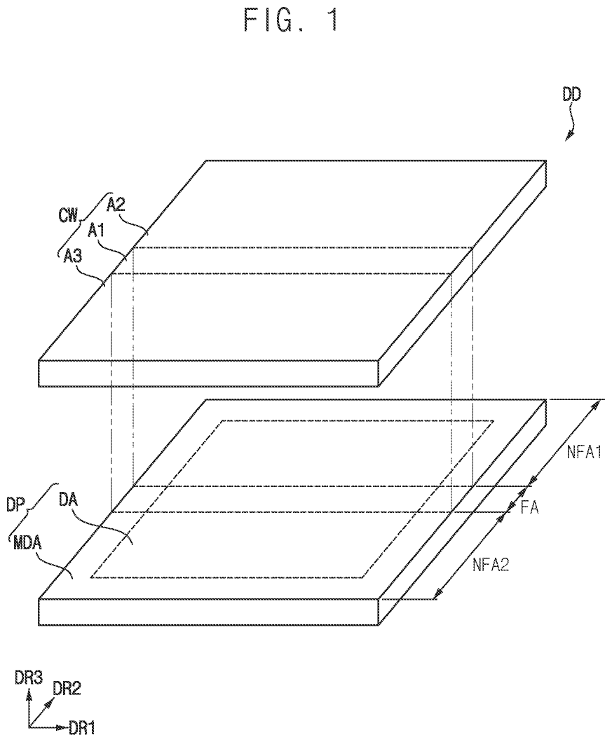

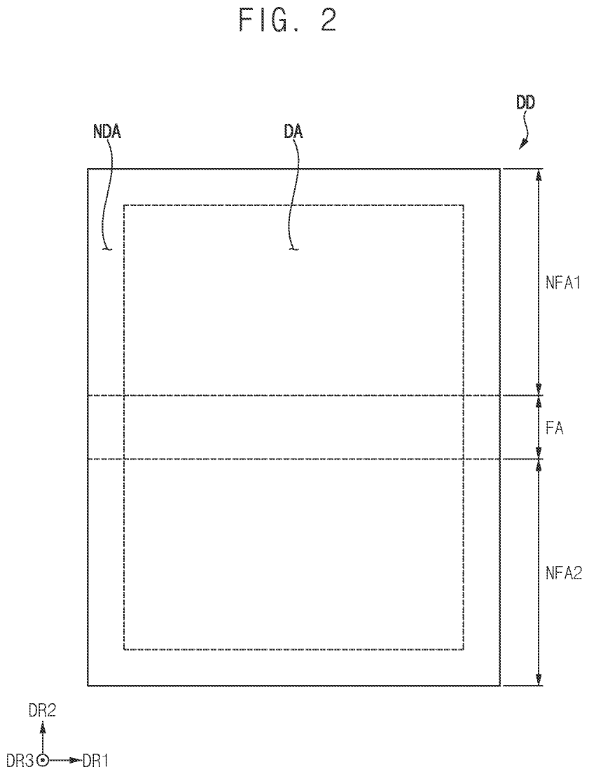

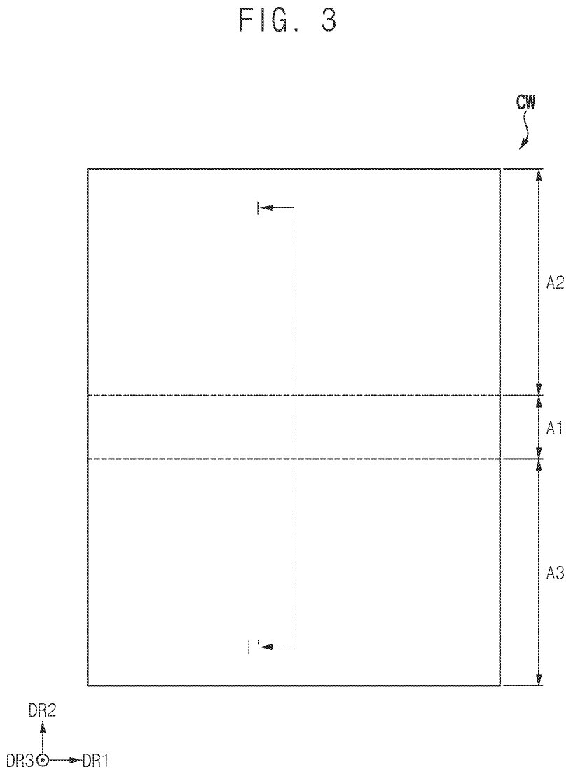

FIG. 1 is a perspective view of a display device according to an embodiment of the disclosure. FIG. 2 is a plan view of a display panel included in the display device of FIG. 1. FIG. 3 is a plan view of a cover window included in the display device of FIG. 1.

Referring to FIGS. 1, 2, and 3, a display device DD according to embodiments may include a display panel DP and a cover window CW.

The display panel DP may include a display area DA and a non-display area NDA. The display area DA may be an area capable of displaying an image by generating light or adjusting transmittance of light provided from an external light source. For example, multiple pixels may be disposed in the display area DA, and the pixels may emit light.

The non-display area NDA may be an area not displaying an image. The non-display area NDA may be positioned adjacent to the display area DA. For example, the non-display area NDA may entirely surround the display area DA.

At least a part of the display device DD may be flexible, and may be foldable in a flexible part (i.e., a foldable area FA). For example, the display area DA may include a foldable area FA that can be bent by an external force to fold the display device DD and first and second non-folding areas NFA1 and NFA2 adjacent to at least a side of the foldable area FA and not foldable. For example, the foldable area FA may have a folding line extending in a first direction DR1. The non-folding area is referred to as a non-folding area, but this is for convenience of explanation. For example, the expression “non-folding” may include not only an embodiment that is hard due to lack of flexibility but also an embodiment that is flexible but not foldable due to having a flexibility less than the foldable area FA.

The cover window CW may be disposed on the display panel DP. The cover window CW may include a first area A1, a second area A2, and a third area A3. The first area A1 may be positioned adjacent to the second area A2 and the third area A3. For example, the first area A1 may be positioned between the second area A2 and the third area A3.

The first area A1 may correspond to the foldable area FA. For example, the first area A1 may have flexibility. For example, the first area A1 and the foldable area FA may overlap with each other in a thickness direction of the display device DD and may have substantially a same area in a plan view.

The second area A2 may correspond to the first non-folding area NFA1. For example, the second area A2 may not be foldable. For example, the second area A2 and the first non-folding area NFA1 may overlap with each other in the thickness direction and may have a same area in a plan view.

The third area A3 may correspond to the second non-folding area NFA2. For example, the third area A3 may not be foldable. For example, the third area A3 and the second non-folding area NFA2 may overlap with each other in the thickness direction and may have a same area in a plan view.

In an embodiment, the cover window CW may include a glass substrate. For example, the cover window CW may include a glass substrate including an alkali aluminosilicate, an alkali aluminoborosilicate, or the like. These may be used alone or in combination with each other. In an embodiment, the glass substrate may further include an alkaline earth oxide.

In an embodiment, the cover window CW may include a glass substrate chemically strengthened by an ion exchange process. A detailed description thereof will be described below.

In the disclosure, a plane may be defined by the first direction DR1 and a second direction DR2 intersecting the first direction DR1. For example, the second direction DR2 may be perpendicular to the first direction DR1. A third direction DR3 may be perpendicular to the plane defined by the first direction DR1 and a second direction DR2.

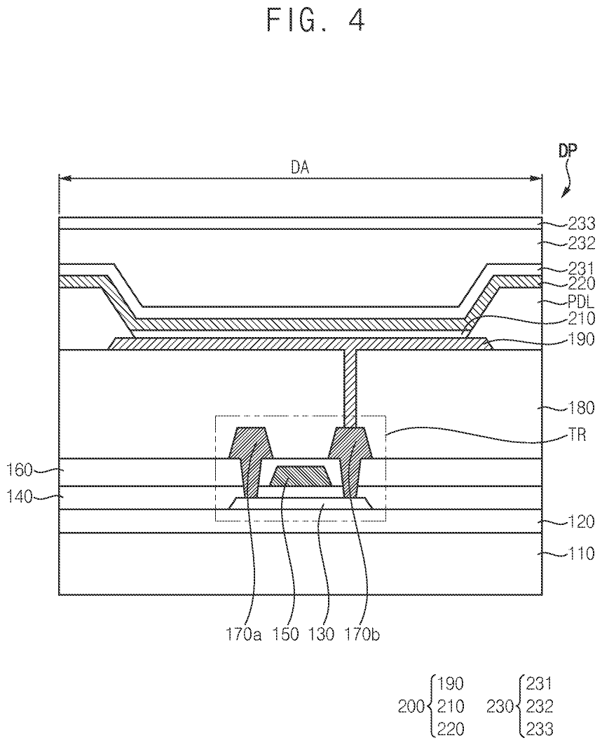

FIG. 4 is a schematic cross-sectional view of a part of the display panel of FIGS. 1 and 2. For example, FIG. 4 is a schematic cross-sectional view of a part of the display area DA of the display panel DP.

Referring to FIG. 4, the display panel DP may include a substrate 110, a buffer layer 120, a gate insulating layer 140, a transistor TR, an interlayer insulating layer 160, a planarization layer 180, a pixel definition layer PDL, a light emitting element 200, and an encapsulation layer 230.

The transistor TR may include an active layer 130, a gate electrode 150, a source electrode 170a, and a drain electrode 170b. The light emitting element 200 may include a lower electrode 190, a light emitting layer 210, and an upper electrode 220. The encapsulation layer 230 may include a first thin film encapsulation layer 231, a second thin film encapsulation layer 232, and a third thin film encapsulation layer 233.

The substrate 110 may include a transparent material or an opaque material. The substrate 110 may include a flexible transparent resin substrate. For example, the substrate 110 may include a polyimide substrate. In another embodiment, the substrate 110 may include a quartz substrate, a synthetic quartz substrate, a calcium fluoride substrate, a soda lime glass substrate, an alkali-free glass substrate, or the like. These may be used alone or in combination with each other.

The buffer layer 120 may be disposed on the substrate 110. The buffer layer 120 may prevent diffusion of metal atoms or impurities from the substrate 110 into the transistor TR. For example, the buffer layer 120 may include an inorganic material such as silicon oxide, silicon nitride, and the like. These may be used alone or in combination with each other.

The active layer 130 may be disposed on the buffer layer 120. The active layer 130 may include a metal oxide semiconductor, an inorganic semiconductor (e.g., amorphous silicon, poly silicon), or an organic semiconductor. The active layer 130 may have a source region, a drain region, and a channel region positioned between the source region and the drain region.

The gate insulating layer 140 may be disposed on the buffer layer 120. The gate insulating layer 140 may sufficiently cover the active layer 130 on the substrate 110 and may have a substantially flat upper surface without creating a step on the active layer 130. In another embodiment, the gate insulating layer 140 may cover the active layer 130 on the substrate 110 and may be disposed along the profile of the active layer 130 to have a uniform thickness. For example, the gate insulating layer 140 may include silicon oxide (SiOₓ), silicon nitride (SiNₓ), silicon carbide (SiCₓ), silicon oxynitride (SiOₓN_{y}), silicon oxycarbide (SiOₓC_{y}), or the like. These may be used alone or in combination with each other.

The gate electrode 150 may be disposed on the gate insulating layer 140. The gate electrode 150 may overlap the channel region of the active layer 130 in a plan view. For example, the gate electrode 150 may include a metal, an alloy, a metal nitride, a conductive metal oxide, a transparent conductive material, or the like. These may be used alone or in combination with each other.

The interlayer insulating layer 160 may be disposed on the gate insulating layer 140. The interlayer insulating layer 160 may sufficiently cover the gate electrode 150 on the substrate 110 and may have a substantially flat upper surface without creating a step on the gate electrode 150. In another embodiment, the interlayer insulating layer 160 may cover the gate electrode 150 on the substrate 110 and may be disposed along the profile of the gate electrode 150 to have a uniform thickness. For example, the interlayer insulating layer 160 may include silicon oxide, silicon nitride, silicon carbide, silicon oxynitride, silicon oxycarbide, or the like. These may be used alone or in combination with each other.

The source electrode 170a and the drain electrode 170b may be disposed on the interlayer insulating layer 160. The source electrode 170a may be connected to the source region of the active layer 130 through a contact hole formed by removing a first part of the gate insulating layer 140 and the interlayer insulating layer 160. The drain electrode 170b may be connected to the drain region of the active layer 130 through a contact hole formed by removing a second part of the gate insulating layer 140 and the interlayer insulating layer 160. For example, each of the source electrode 170a and the drain electrode 170b may include a metal, an alloy, a metal nitride, a conductive metal oxide, a transparent conductive material, or the like. These may be used alone or in combination with each other.

Accordingly, the transistor TR including the active layer 130, the gate electrode 150, the source electrode 170a, and the drain electrode 170b may be disposed in the display area DA on the substrate 110.

The planarization layer 180 may be disposed on the interlayer insulating layer 160. The planarization layer 180 may sufficiently cover the source electrode 170a and the drain electrode 170b. The planarization layer 180 may include an organic material or an inorganic material. In an embodiment, the planarization layer 180 may include an organic material. For example, the planarization layer 180 may include an organic material such as a polyimide-based resin, a photoresist, a polyacryl-based resin, a polyamide-based resin, a siloxane-based resin, and the like. These may be used alone or in combination with each other.

The lower electrode 190 may be disposed on the planarization layer 180. The lower electrode 190 may be connected to the drain electrode 170b through a contact hole formed by removing a part of the planarization layer 180. For example, the lower electrode 190 may include a metal, an alloy, a metal nitride, a conductive metal oxide, a transparent conductive material, or the like. These may be used alone or in combination with each other.

The pixel defining layer PDL may be disposed on the planarization layer 180. An opening exposing at least a part of an upper surface of the lower electrode 190 may be defined in the pixel defining layer PDL. The pixel defining layer PDL may include an organic material or an inorganic material. For example, the pixel defining layer PDL may include an organic material such as a polyimide-based resin, a photoresist, a polyacrylic resin, a polyamide-based resin, a siloxane-based resin, and the like. These may be used alone or in combination with each other.

The light emitting layer 210 may be disposed on the lower electrode 190. The light emitting layer 210 may be disposed on the part of the lower electrode 190 exposed by the opening of the pixel defining layer PDL. The light emitting layer 210 may be formed using at least one of a light emitting material capable of emitting red light, green light, and blue light. In another embodiment, the light emitting layer 210 may emit white light by stacking multiple light emitting materials capable of generating different color lights such as red light, green light, and blue light.

The upper electrode 220 may be disposed on the pixel defining layer PDL and the light emitting layer 210. The upper electrode 220 may be entirely disposed in the display area DA. For example, the upper electrode 220 may include a metal, an alloy, a metal nitride, a conductive metal oxide, a transparent conductive material, or the like. These may be used alone or in combination with each other.

Accordingly, the light emitting element 200 including the lower electrode 190, the light emitting layer 210, and the upper electrode 220 may be disposed in the display area DA on the substrate 110.

The first thin film encapsulation layer 231 may be disposed on the upper electrode 220. The first thin film encapsulation layer 231 may prevent the light emitting layer 210 from deteriorating due to penetration of moisture, oxygen, and the like. The first thin film encapsulation layer 231 may also protect the display panel DP from external impact. For example, the first thin film encapsulation layer 231 may include an inorganic material having flexibility.

The second thin film encapsulation layer 232 may be disposed on the first thin film encapsulation layer 231. The second thin film encapsulation layer 232 may improve flatness of the display panel DP and protect the display panel DP. For example, the second thin film encapsulation layer 232 may include an organic material having flexibility.

The third thin film encapsulation layer 233 may be disposed on the second thin film encapsulation layer 232. The third thin film encapsulation layer 233 together with the first thin film encapsulation layer 231 may prevent the light emitting layer 210 from deteriorating due to penetration of moisture, oxygen, and the like. The third thin film encapsulation layer 233 may protect the display panel DP together with the first thin film encapsulation layer 231 and the second thin film encapsulation layer 232 from external impact. For example, the third thin film encapsulation layer 233 may include an inorganic material having flexibility.

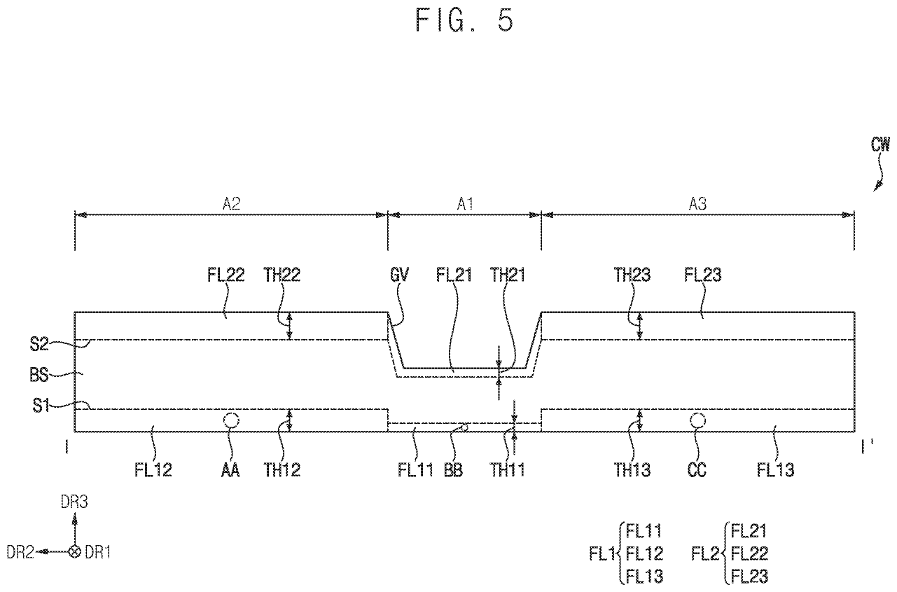

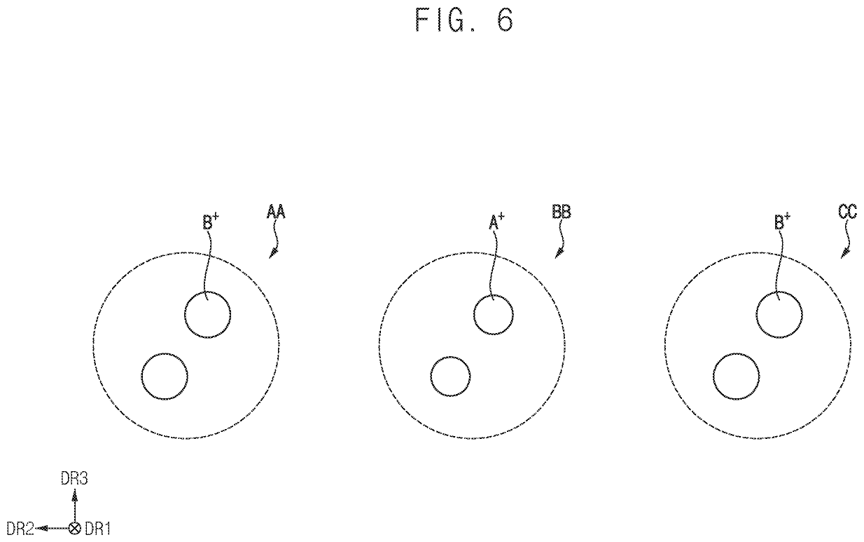

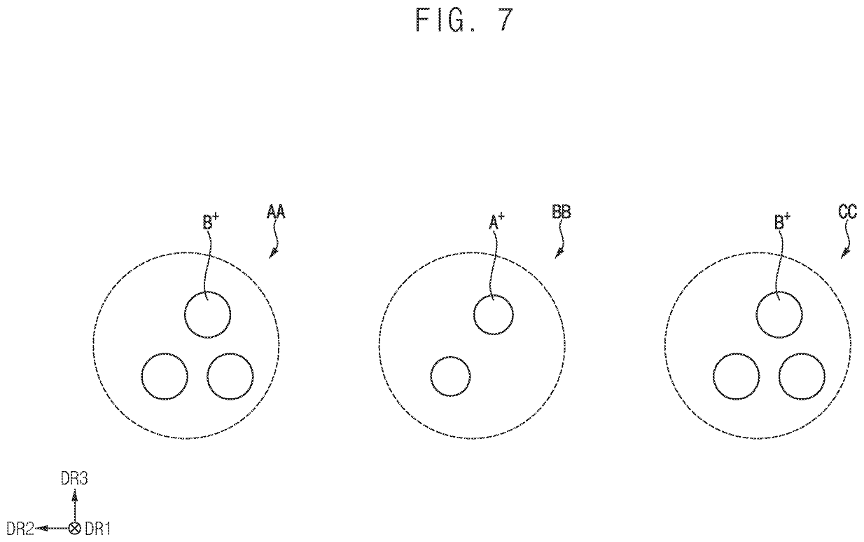

FIG. 5 is a schematic cross-sectional view of the cover window of FIG. 3 taken along line I-I′. FIG. 6 is a schematic cross-sectional view of areas AA, BB, and CC of FIG. 5 according to an embodiment. FIG. 7 is a schematic cross-sectional view of areas AA, BB, and CC of FIG. 5 according to an embodiment.

Referring to FIGS. 5, 6, and 7, the cover window CW may include a base layer BS, a first functional layer FL1, and a second functional layer FL2.

As described above, the cover window CW may include a first area A1, a second area A2, and a third area A3.

A thickness of the cover window CW in the first area A1 may be less than a thickness of the cover window CW in the second and third areas A2 and A3 in a thickness direction of the display device DD. For example, in an embodiment, a groove GV may be formed on an upper surface of the cover window CW in the first area A1. Accordingly, the cover window CW may be readily foldable in the first area A1.

As described above, the cover window CW may include a glass substrate. In an embodiment, the cover window CW may include amorphous glass in the first area A1 and crystalline glass in the second and third areas A2 and A3.

The base layer BS may function as a body of the cover window CW. The first functional layer FL1 is disposed on a first surface S1 of the base layer BS, and the second functional layer FL2 is disposed on a second surface S2 of the base layer BS. For example, the second surface S2 may correspond to a surface on which the groove GV is defined, and the first surface S1 may be opposite to the second surface S2.

In an embodiment, each of the first and second functional layers FL1 and FL2 may be formed through an ion exchange process on the cover window CW. Accordingly, each of the first and second functional layers FL1 and FL2 may be formed on a surface of the base layer BS. The base layer BS may be a part of the cover window CW on which ion exchange is not performed. For example, the thickness of each of the first and second functional layers FL1 and FL2 may correspond to a depth of compressive stress by the ion exchange process.

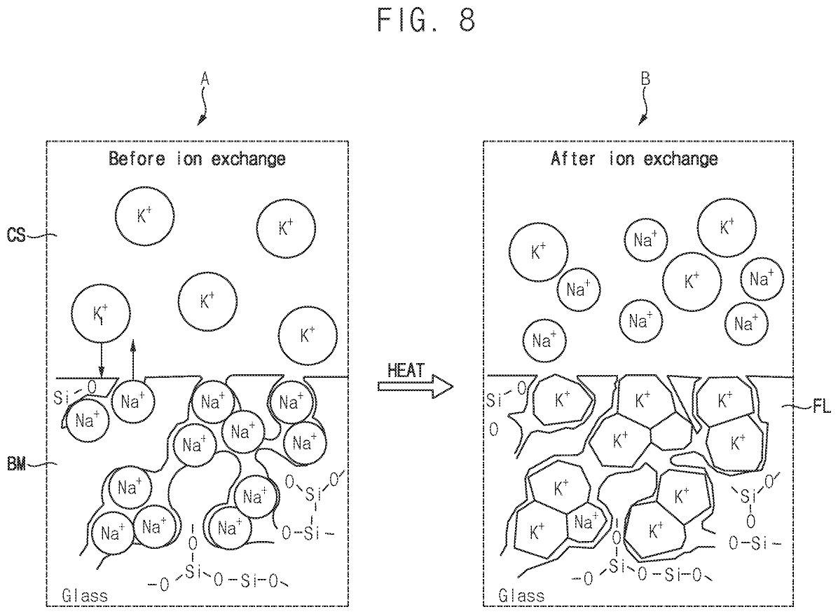

The ion exchange process may be a process of exchanging ions having a small ion radius present on a surface of a glass with an ion having a large ion radius. A detailed description of the ion exchange process will be described below with reference to FIG. 8.

The first functional layer FL1 may include a first part FL11, a second part FL12, and a third part FL13. The first part FL11 of the first functional layer FL1 may be disposed in the first area A1, the second part FL12 of the first functional layer FL1 may be disposed in the second area A2, and the third part FL13 of the first functional layer FL1 may be disposed in the third area A3.

The first part FL11 of the first functional layer FL1 may have a first thickness TH11, and the second and third parts FL12 and FL13 of the first functional layer FL1 may have second and third thicknesses TH12 and TH13, respectively in the thickness direction of the display device DD. In an embodiment, the second and third thicknesses TH12 and TH13 may be the same, and each of the second and third thicknesses TH12 and TH13 may be greater than the first thickness TH11. For example, the depth of compressive stress of the first functional layer FL1 in the second and third areas A2 and A3 may be greater than the depth of compressive stress of the first functional layer FL1 in the first area A1.

Due to the ion exchange process, the first part FL11 of the first functional layer FL1 may have a first compressive stress, and each of the second and third parts FL12 and FL13 of the first functional layer FL1 may have a second compressive stress. As the first and second compressive stresses decreases according to a function from the lower surface of the first functional layer FL1 to the first surface S1 of the base layer BS, the first and second compressive stresses may be zero on the first surface S1 of the base layer BS. In an embodiment, a maximum value of the second compressive stress may be greater than a maximum value of the first compressive stress.

The second functional layer FL2 may include a first part FL21, a second part FL22, and a third part FL23. The first part FL21 of the second functional layer FL2 may be disposed in the first area A1, and the second part FL22 of the second functional layer FL2 may be disposed in the second area A2, and the third part FL23 of the second functional layer FL2 may be disposed in the third area A3.

The first part FL21 of the second functional layer FL2 may have a first thickness TH21, and the second and third parts FL22 and FL23 of the second functional layer FL2 may have second and third thicknesses TH22 and TH23, respectively in the thickness direction of the display device DD. In an embodiment, the second and third thicknesses TH22 and TH23 may be the same, and each of the second and third thicknesses TH22 and TH23 may be greater than the first thickness TH21. For example, the depth of compressive stress of the second functional layer FL2 in the second and third areas A2 and A3 may be greater than the depth of compressive stress of the second functional layer FL2 in the first area A1.

Due to the ion exchange process, the first part FL21 of the second functional layer FL2 may have a first compressive stress, and each of the second and third parts FL21 and FL22 of the second functional layer FL2 may have a second compressive stress. As the first and second compressive stresses decreases according to a function from the upper surface of the second functional layer FL2 to the second surface S2 of the base layer BS, the first and second compressive stresses may be zero on the second surface S2 of the base layer BS. In an embodiment, a maximum value of the second compressive stress may be greater than a maximum value of the first compressive stress.

A tensile stress may be formed in the base layer BS. In an embodiment, a substantially same tensile stress may be formed in the first, second, and third areas A1, A2, and A3 of the base layer BS.

In an embodiment, the first part FL11 of the first functional layer FL1 may include a first ion A⁺, and each of the second and third parts FL12 and FL13 of the first functional layer FL1 may include a second ion B⁺. For example, the first part FL11 of the first functional layer FL1 and the second and third parts FL12 and FL13 of the first functional layer FL1 may include different types of ions.

In an embodiment, an ionic radius of the second ion B⁺ may be greater than an ionic radius of the first ion A⁺. Accordingly, the depth of compressive stress of the first functional layer FL1 in the second and third areas A2 and A3 may be greater than the depth of the compressive stress of the first functional layer FL1 in the first area A1.

The first part FL11 of the first functional layer FL1 may include the first ion A⁺ by a first amount (or a first amount of the first ion A+) and each of the second and third parts FL12 and FL13 of the first functional layer FL1 may include the second ion B⁺ by a second amount (or a second amount of the second ion B+). In an embodiment, the first amount and the second amount may be the same (see FIG. 6). In another embodiment, the second amount may be greater than the first amount (see FIG. 7).

The second functional layer FL2 and the first functional layer FL1 may be implemented substantially the same. For example, the second and third parts FL22 and FL23 of the second functional layer FL2 and the first part F21 of the second functional layer FL2 may include different types of ions.

Although FIG. 5 illustrates the cover window CW including the first functional layer FL1 and the second functional layer FL2, embodiments of the disclosure are not limited thereto. For example, in an embodiment the first functional layer FL1 or the second functional layer FL2 may be omitted in the cover window CW.

FIG. 8 is a schematic diagram illustrating a dry ion exchange process.

Referring to FIG. 8, as described above, the ion exchange process may be a process of exchanging ions having a small ion radius present on the surface of a base member BM (e.g., glass) with ions having a large ion radius. After the ion exchange process is performed, as the ion radius of the ions present on the surface of the base member BM is large or the amount of the ions present on the surface of the base member BM increases, the ions may generate high compressive stress. Accordingly, a strength of the functional layer FL may be increased. For example, the functional layer FL may correspond to each of the first and second functional layers FL1 and FL2.

The ion exchange process may include a wet ion exchange process and a dry ion exchange process.

The wet ion exchange process may supply ions to a glass by immersing the glass in a salt bath including molten salt. Ion exchange may be performed by permeating ions into the glass by diffusion due to a concentration difference.

In the dry ion exchange process, a coating solution or paste including molten salt may be applied to the surface of a glass. In case that the glass applied with the coating solution is heated, ion exchange may be performed by ions with a small ionic radius diffusing and escaping from the glass, and ions with a large ionic radius penetrating into the glass.

In an embodiment, in order to implement the first and second functional layers FL1 and FL2 having compressive stress, the cover window CW may be formed through a dry ion exchange process. For example, ions exchanged through a dry ion exchange process may include alkali metal ions.

As shown in FIG. 8, A of FIG. 8 is a view for illustrating a base member BM and a coating solution CS before a dry ion exchange process is performed, and B of FIG. 8 is a view for illustrating the functional layer FL after the dry ion exchange process is performed. For example, potassium ions (K⁺) having a large ion radius may be applied on the base member BM including sodium ions (Na⁺) having a small ion radius. In case that the base member BM applied with the coating solution CS is heated, the sodium ions (Na⁺) may diffuse and escape from the base member BM, and the potassium ions (K⁺) may penetrate into the base member BM.

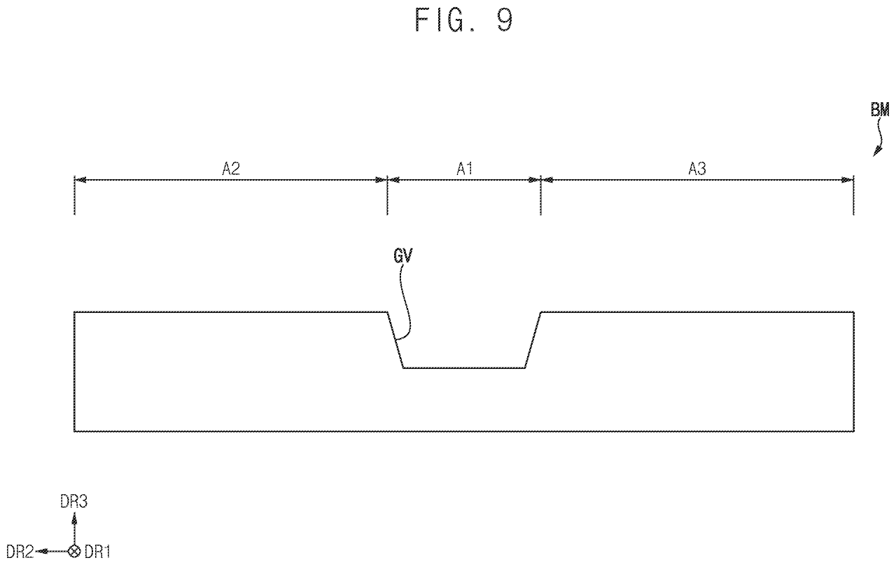

FIGS. 9, 10, 11, and 12 are schematic cross-sectional views illustrating a method for manufacturing the cover window of FIG. 5.

Referring to FIG. 9, the base member BM including the first area A1, the second area A2, and the third area A3 may be formed. In an embodiment, a groove GV may be formed in the first area A1 by removing a part of the base member BM. The base member BM may be a glass substrate including ions having relatively a small ion radius (e.g., lithium ions (Li⁺) and sodium ions (Na⁺)).

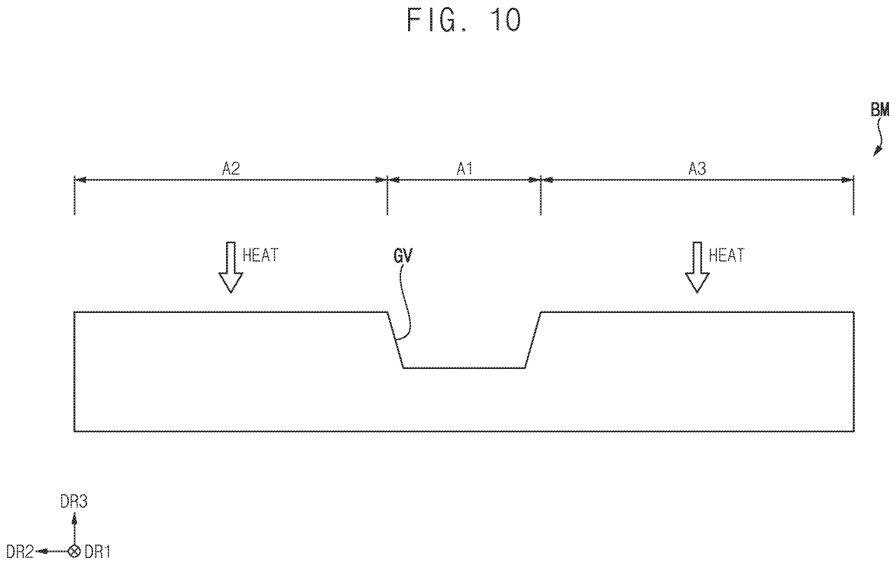

Referring to FIG. 10, crystallization may be performed by heating the second and third areas A2 and A3 of the base member BM. Accordingly, the base member BM may be formed of amorphous glass in the first area A1 and formed of crystalline glass in the second and third areas A2 and A3.

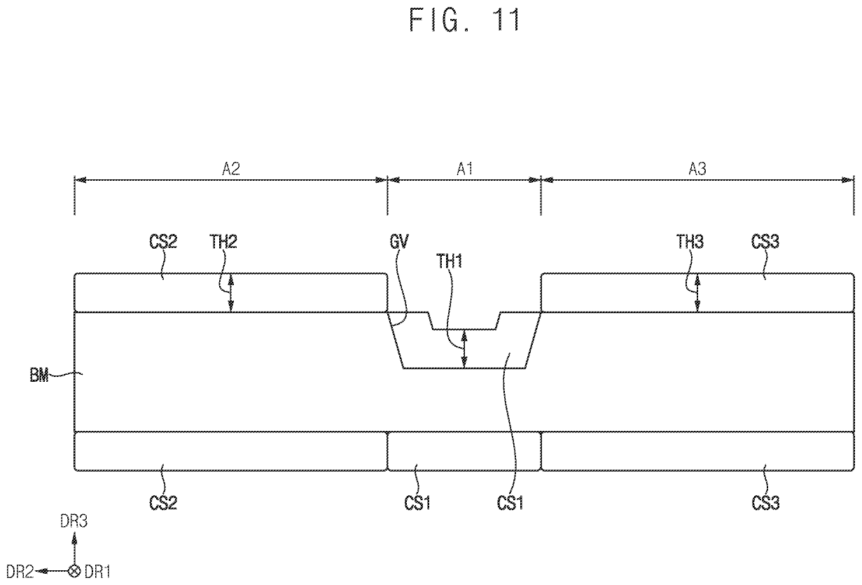

Referring to FIG. 11, first, second, and third coating solutions CS1, CS2, and CS3 may be applied to upper and lower surfaces of the base member BM, respectively. For example, the first coating solution CS1 may be applied to the first area A1, the second coating solution CS2 may be applied to the second area A2, and the third coating solution CS3 may be applied to the third area A3.

In an embodiment, the first coating solution CS1 may include a first ion (e.g., the first ion A⁺ in FIGS. 6 and 7), and each of the second and third coating solutions CS2 and CS3 may include a second ion (e.g., the second ion B⁺ in FIGS. 6 and 7) different from the first ion.

The base member BM may include ions different from the first and second ions and having an ion radius smaller than each of the first and second ions.

The first coating solution CS1 may include the first ion by a first amount and each of the second and third coating solutions CS2 and CS3 may include the second ion by a second amount. In an embodiment, the first amount and the second amount may be the same. In another embodiment, the second amount may be greater than the first amount.

The first coating solution CS1 may have a first thickness TH1, the second coating solution CS2 may have a second thickness TH2, and the third coating solution CS3 may have a third thickness TH3 in the thickness direction of the display device DD. In an embodiment, the first, second, and third thicknesses TH1, TH2, and TH3 may be substantially the same. However, the disclosure is not limited thereto.

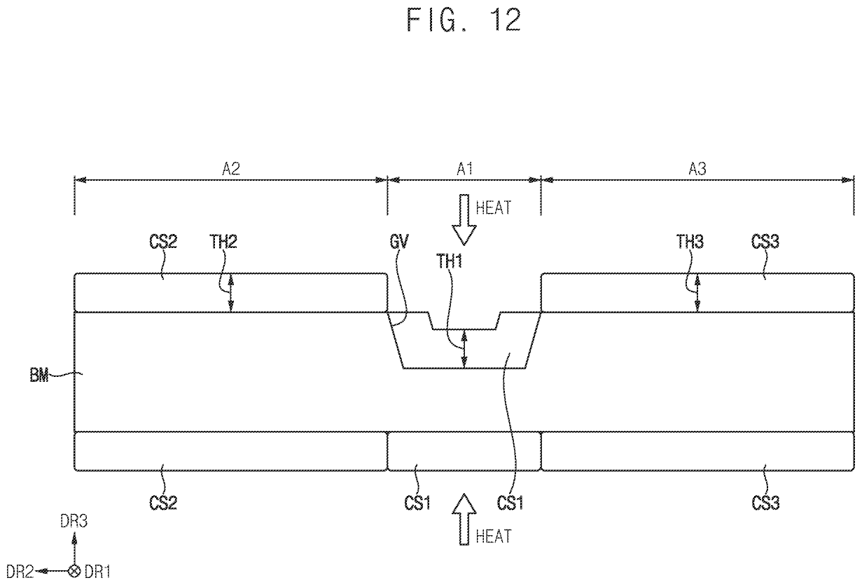

Referring to FIG. 12, the base member BM to which the first, second, and third coating solutions CS1, CS2, and CS3 are applied may be heated.

Referring back to FIG. 5, by heating the base member BM to which the first, second, and third coating solutions CS1, CS2, and CS3 are applied, ions may penetrate the lower surface of the base member BM to form the first functional layer FL1, and ions may penetrate the upper surface of the base member BM to form the second functional layer FL2.

After the first and second functional layers FL1 and FL2 are formed, the first, second, and third coating solutions CS1, CS2, and CS3 may be removed through cleaning.

Accordingly, the cover window CW including the base layer BS, the first functional layer FL1 and the second functional layer FL2 may be manufactured. The base layer BS may be a part of the base member BM in which ion exchange is not performed.

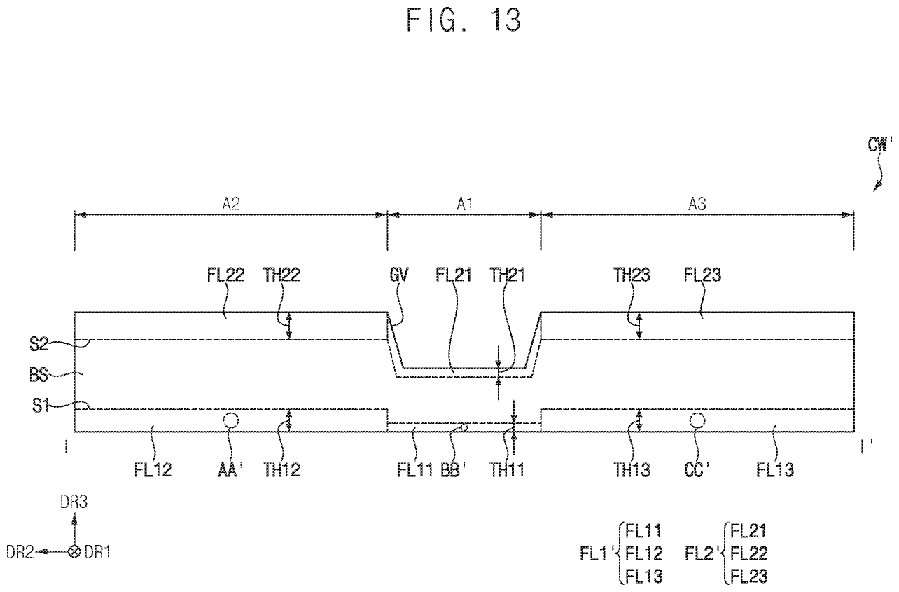

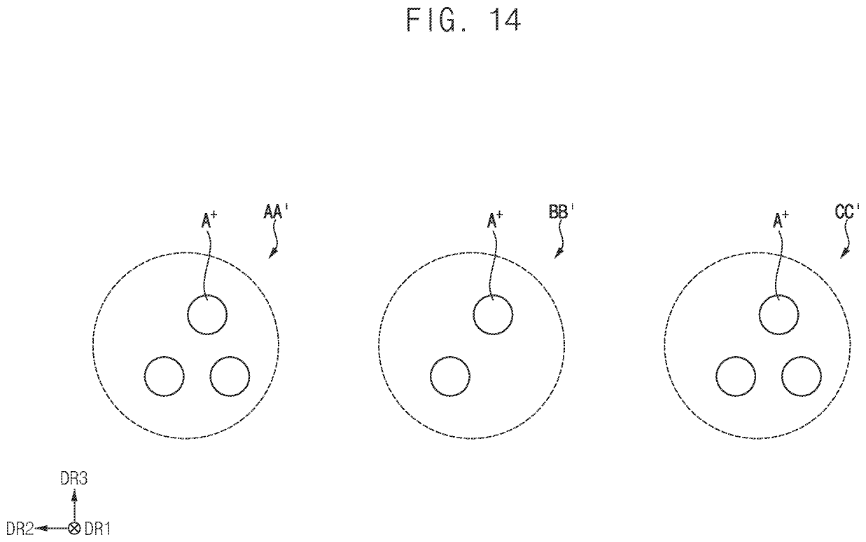

FIG. 13 is a schematic cross-sectional view of a cover window according to another embodiment of the disclosure. FIG. 14 is a schematic cross-sectional view of areas AA′, BB′, and CC′ of FIG. 13.

Referring to FIGS. 13 and 14, the cover window CW′ may include a base layer BS, a first functional layer FL1′, and a second functional layer FL2′. However, a cover window CW′ described with reference to FIGS. 13 and 14 and the cover window CW described with reference to FIGS. 5, 6, and 7 may be substantially the same as or similar except for the amount and type of ions in the second and third areas A2 and A3. Hereinafter, redundant descriptions are omitted or simplified.

The cover window CW′ may include a first area A1, a second area A2, and a third area A3.

In an embodiment, a groove GV may be formed on an upper surface of the cover window CW′ in the first area A1. Accordingly, the cover window CW′ may be readily foldable in the first area A1.

In an embodiment, the cover window CW′ may include amorphous glass in the first area A1 and crystalline glass in the second and third areas A2 and A3.

The first functional layer FL1′ may be disposed on a first surface S1 of the base layer BS, and the second functional layer FL2′ may be disposed on a second surface S2 of the base layer BS.

The first functional layer FL1′ may include a first part FL11, a second part FL12, and a third partFL13. The first part FL11 of the first functional layer FL1′ may be disposed in the first area A1, the second part FL12 of the first functional layer FL1′ may be disposed in the second area A2, and the third part FL13 of the first functional layer FL1′ may be disposed in the third area A3.

The first part FL11 of the first functional layer FL1′ may have a first thickness TH11, and the second and third parts FL12 and FL13 of the first functional layer FL1′ may have second and third thicknesses TH12 and TH13, respectively in the thickness direction of the display device DD. In an embodiment, the second and third thicknesses TH12 and TH13 may be the same, and each of the second and third thicknesses TH12 and TH13 may be greater than the first thickness TH11.

The second functional layer FL2′ may include a first part FL21, a second part FL22, and a third part FL23. The first part FL21 of the second functional layer FL2′ may be disposed in the first area A1, the second part FL22 of the second functional layer FL2′ may be disposed in the second A2, and the third part FL23 of the second functional layer FL2′ may be disposed in the third area A3.

The first part FL21 of the second functional layer FL2′ may have a first thickness TH21, and the second and third parts FL22 and FL23 of the second functional layer FL2′ may have second and third thicknesses TH22 and TH23, respectively in the thickness direction of the display device DD. In an embodiment, the second and third thicknesses TH22 and TH23 may be the same, and each of the second and third thicknesses TH22 and TH23 may be greater than the first thickness TH21.

In an embodiment, the first part FL11 of the first functional layer FL1′ may include a first ion A⁺, and the second and third parts FL12 and FL13 of the first functional layer FL1′ may include the first ion A⁺. For example, the first part FL11, the second part FL12, and the third part FL13 of the first functional layer FL1′ may include ions of a same type.

The first part FL11 of the first functional layer FL1′ may include the first ion A⁺ by a first amount and each of the second and third parts FL12 and FL13 of the first functional layer FL1′ may include the first ion A⁺ by a second amount. In an embodiment, the second amount may be greater than the first amount.

The second functional layer FL2′ and the first functional layer FL1′ may be implemented substantially the same.

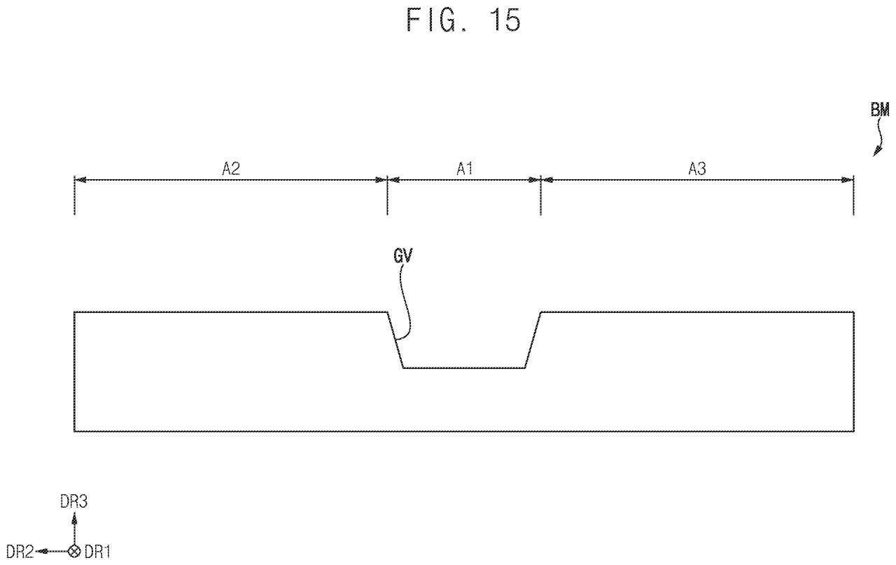

FIGS. 15, 16, 17, and 18 are schematic cross-sectional views illustrating a method for manufacturing the cover window of FIG. 13 according to an embodiment.

Referring to FIG. 15, a base member BM including the first area A1, the second area A2, and the third area A3 may be formed. In an embodiment, a groove GV may be formed in the first area A1 by removing a part of the base member BM. The base member BM may be a glass substrate including ions having relatively small ion radius (e.g., lithium ions (Li⁺) and sodium ions (Na⁺)).

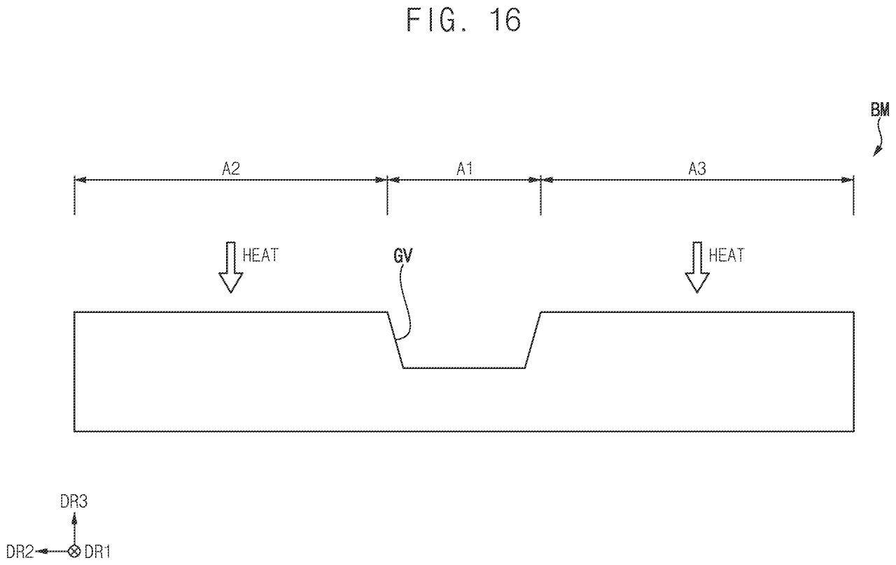

Referring to FIG. 16, crystallization may be performed by heating the second and third areas A2 and A3 of the base member BM. Accordingly, the base member BM may be formed of amorphous glass in the first area A1 and formed of crystalline glass in the second and third areas A2 and A3.

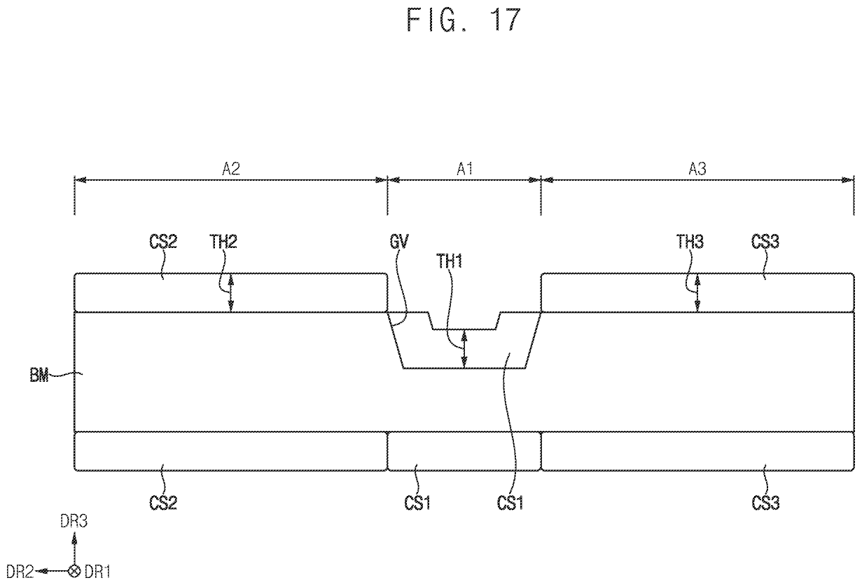

Referring to FIG. 17, first, second, and third coating solutions CS1, CS2, and CS3 may be applied to upper and lower surfaces of the base member BM. For example, the first coating solution CS1 may be applied to the first area A1, the second coating solution CS2 may be applied to the second area A2, and the third coating solution CS3 may be applied to the third area A3.

In an embodiment, the first coating solution CS1 may include a first ion (e.g., the first ion A+ in FIG. 14) and a third ion, and each of the second and third coating solutions

CS2 and CS3 may each include the first ion and the third ion. The ratio of the first ion to the third ion in the first coating solution CS1 and the ratio of the first ion to the third ion in the second and third coating solutions CS2 and CS3 may be different.

In another embodiment, the first coating solution CS1 may include the first ion and the third ion, and each of the second and third coating solutions CS2 and CS3 may include the first ion.

The base member BM may include the third ion. For example, the ionic radius of the first ion may be greater than the ionic radius of the third ion.

The first coating solution CS1 may include the first ion by a first amount and each of the second and third coating solution CS2 and CS3 may include the first ion by a second amount. In an embodiment, the second amount may be greater than the first amount.

The first coating solution CS1 may have a first thickness TH1, the second coating solution CS2 may have a second thickness TH2, and the third coating solution CS3 may have a third thickness TH3 in the thickness direction of the display device DD. In an embodiment, the first, second, and third thicknesses TH1, TH2, and TH3 may be substantially the same.

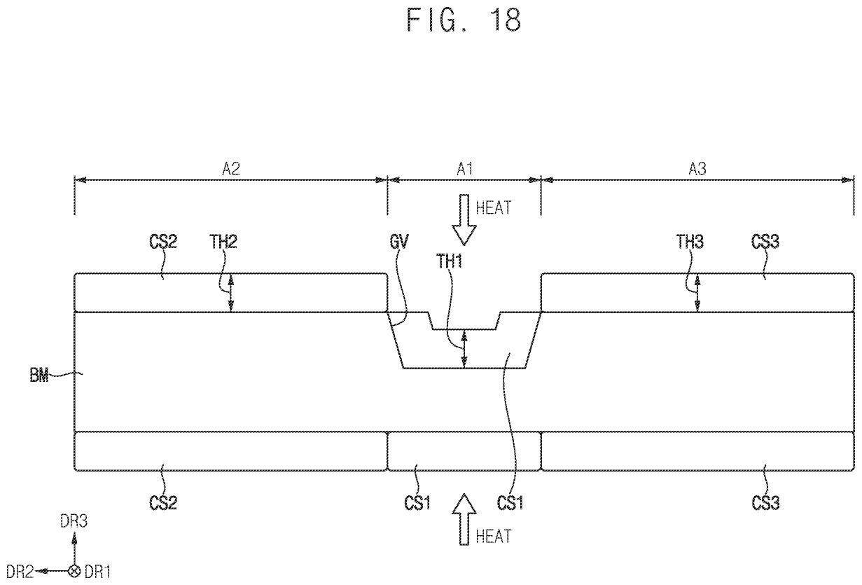

Referring to FIG. 18, the base member BM to which the first, second, and third coating solutions CS1, CS2, and CS3 are applied may be heated.

Referring back to FIG. 13, by heating the base member BM to which the first, second, and third coating solutions CS1, CS2, and CS3 are applied, ions may penetrate the lower surface of the base member BM to form the first functional layer FL1, and ions may penetrate the upper surface of the base member BM to form the second functional layer FL2.

After the first and second functional layers FL1 and FL2 are formed, the first, second, and third coating solutions CS1, CS2, and CS3 may be removed through cleaning.

Accordingly, the cover window CW′ including the base layer BS, the first functional layer FL1, and the second functional layer FL2 may be manufactured.

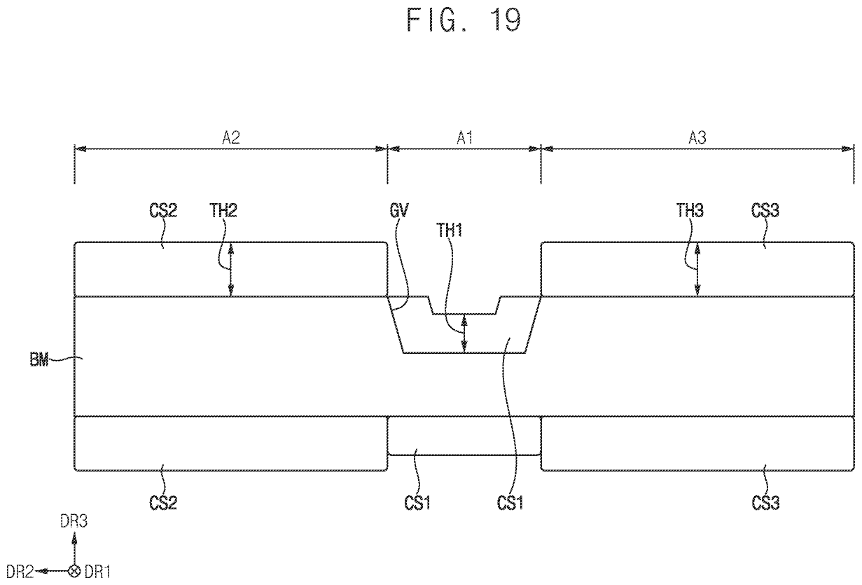

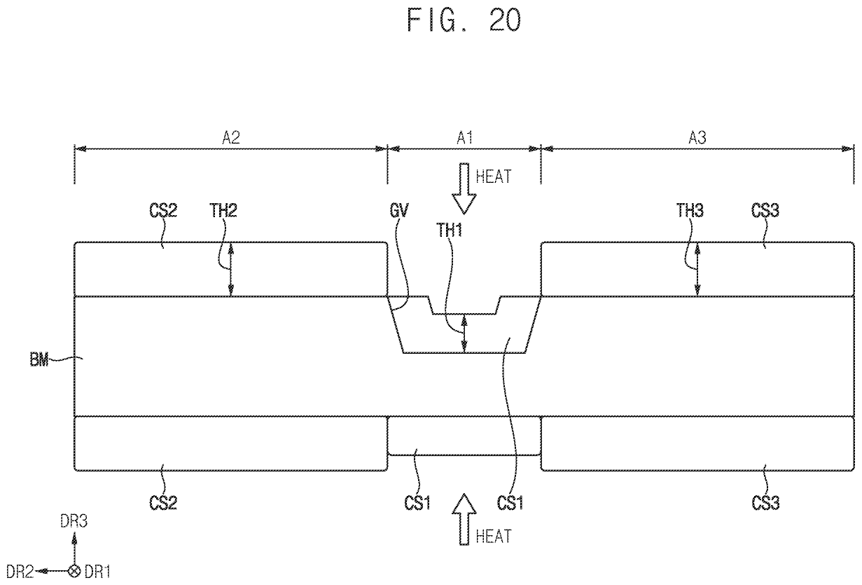

FIGS. 19 and 20 are schematic cross-sectional views illustrating a method for manufacturing the cover window of FIG. 13 according to an embodiment.

Referring back to FIGS. 15 and 16, the base member BM including the first area A1, the second area A2, and the third area A3, and having the groove GV formed in the first area A1 may be formed.

Crystallization may be performed by heating the second and third areas A2 and A3 of the base member BM. Accordingly, the base member BM may be formed of amorphous glass in the first area A1 and formed of crystalline glass in the second and third areas A2 and A3.

Referring to FIG. 19, the first, second, and third coating solutions CS1, CS2, and CS3 may be applied to the upper and lower surfaces of the base member BM. For example, the first coating solution CS1 may be applied to the first area A1, the second coating solution CS2 may be applied to the second area A2, and the third coating solution CS3 may be applied to the third area A3.

In an embodiment, the first coating solution CS1 may include a first ion (e.g., the first ion A⁺ in FIG. 14) and a third ion, and each of the second and third coating solutions CS2 and CS3 may include the first ion and the third ion. The ratio of the first ion to the third ion in the first, second, and third coating solutions CS1, CS2, and CS3 may be same.

In another embodiment, the first coating solution CS1 may include the first ion, and each of the second and third coating solutions CS2 and CS3 may include the first ion.

The first coating solution CS1 may include the first ion by a first amount and each of the second and third solutions CS2 and CS3 may include the first ion by a second amount. In an embodiment, the second amount may be greater than the first amount.

The first coating solution CS1 may have a first thickness TH1, the second coating solution CS2 may have a second thickness TH2, and the third coating solution CS3 has a third thickness TH3 in the thickness direction of the display device DD. In an embodiment, the second and third thicknesses TH2 and TH3 may be the same, and each of the second and third thicknesses TH2 and TH3 may be greater than the first thickness TH1.

Referring to FIG. 20, the base member BM to which the first, second, and third coating solutions CS1, CS2, and CS3 are applied may be heated.

Referring back to FIG. 13, by heating the base member BM to which the first, second, and third coating solutions CS1, CS2, and CS3 are applied, ions may penetrate the lower surface of the base member BM to form the first functional layer FL1, and ions may penetrate the upper surface of the base member BM to form the second functional layer FL2.

After the first and second functional layers FL1 and FL2 are formed, the first, second, and third coating solutions CS1, CS2, and CS3 may be removed through cleaning.

Accordingly, the cover window CW′ including the base layer BS, the first functional layer FL1, and the second functional layer FL2 may be manufactured.

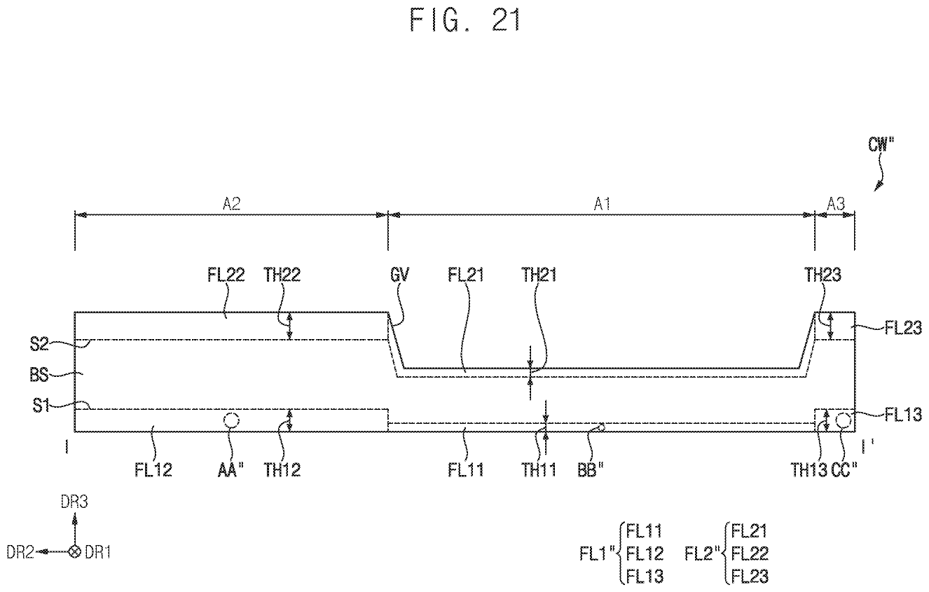

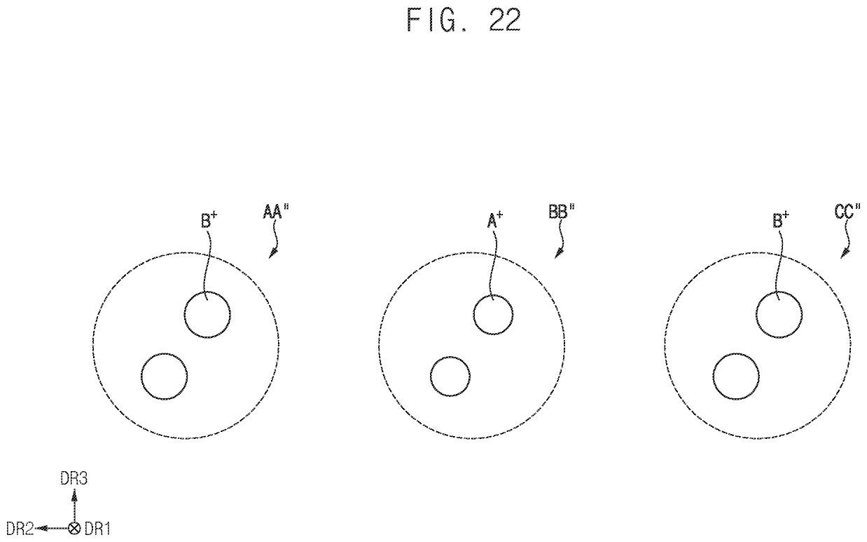

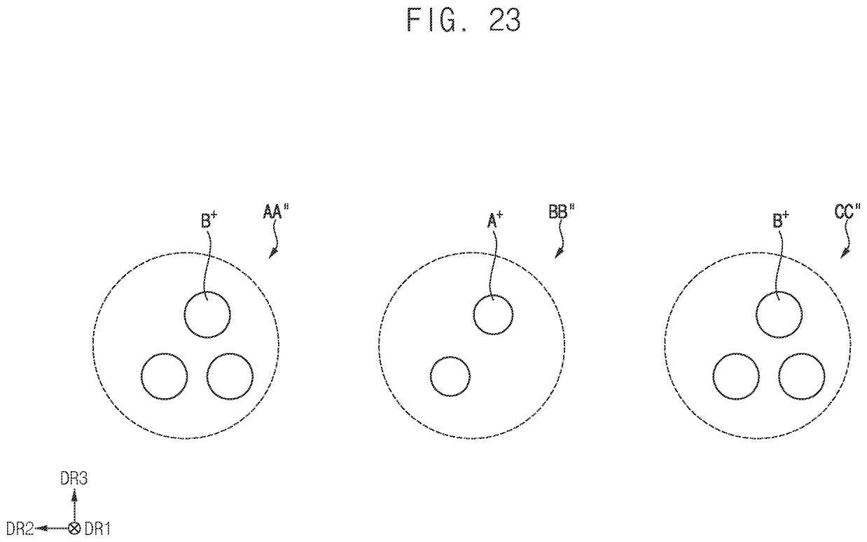

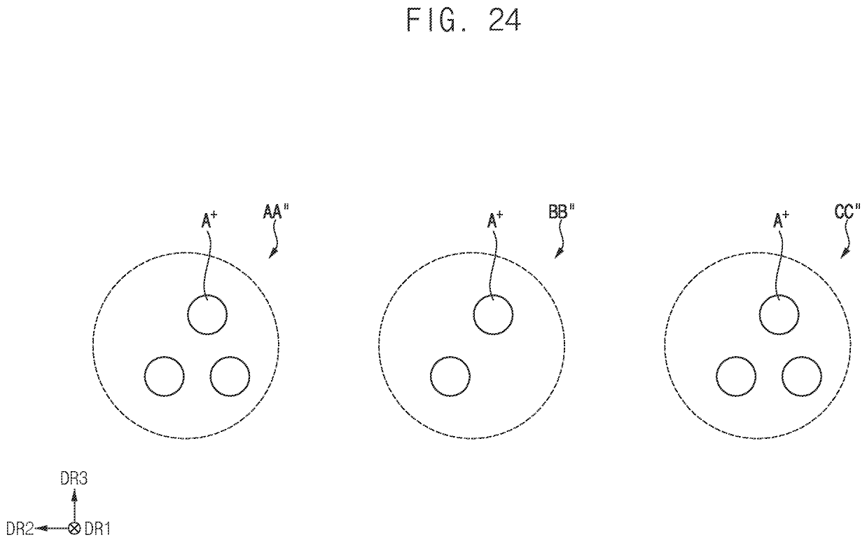

FIG. 21 is a schematic cross-sectional view of a cover window according to another embodiment of the disclosure. FIG. 22 is a schematic cross-sectional view of areas AA″, BB″ and CC″ of FIG. 21 according to an embodiment. FIGS. 23 and 24 are schematic cross-sectional views of areas AA″, BB″ and CC″ of FIG. 21 according to an embodiment.

Referring to FIGS. 22, 22, 23, and 24, a cover window CW″ may include a base layer BS, a first functional layer FL1″, and a second functional layer FL2″. However, the cover window CW″ described with reference to FIGS. 22, 22, 23, and 24 and the cover windows CW and CW′ described with reference to FIGS. 13 and 14 may be substantially the same or similar except for the size of the first area A1. Hereinafter, redundant descriptions are omitted or simplified.

The cover window CW″ may include a first area A1, a second area A2, and a third area A3. In an embodiment, the area of the first area A1 having flexibility shown in FIG. 21 may be greater than the area of the first area A1 having flexibility shown in FIGS. 3, 5 and 13. In an embodiment, the cover window CW″ may be applied to a slidable display device.

In an embodiment, the first part FL11 of the first functional layer FL1″ may include a first ion A⁺, and the second and third parts FL12 and FL13 of the first functional layer FL1″ may include a second ion B⁺. For example, the first part FL11 of the first functional layer FL1″ and the second and third parts FL12 and FL13 of the first functional layer FL1″ may include different types of ions.

In an embodiment, the ionic radius of the second ion B⁺ may be greater than the ionic radius of the first ion A⁺. Accordingly, the depth of compressive stress of the first functional layer FL1″ in the second and third areas A2 and A3 may be greater than the depth of compressive stress of the first functional layer FL1″ in the first area A1.

The first part FL11 of the first functional layer FL1″ may include the first ion A⁺ by a first amount and each of the second and third parts FL12 and FL13 of the first functional layer FL1″ may include the second ion B⁺ by a second amount. In an embodiment, the first amount and the second amount may be the same (see FIG. 22). In another embodiment, the second amount may be greater than the first amount (see FIG. 23).

In an embodiment, the first part FL11 of the first functional layer FL1″ may include the first ion A⁺, and each of the second and third parts FL12 and FL13 of the first functional layer FL1″ may include the first ion A⁺ (see FIG. 24). For example, the first part F11, the second part F12, and the third part F13 of the first functional layer FL1″ may include a same type of ions.

The first part FL11 of the first functional layer FL1″ may include the first ion A⁺ by a first amount and each of the second and third parts FL12 and FL13 of the first functional layer FL1″ may include the first ion A⁺ by a second amount. In an embodiment, the second amount may be greater than the first amount.

The second functional layer FL2″ and the first functional layer FL1″ may be implemented substantially the same.

A display device according to embodiments of the disclosure may include a display panel and a cover window disposed on the display panel and including a first area having flexibility and a second area positioned adjacent to the first area. The cover window may include a base layer and a functional layer disposed on at least one surface of the base layer and formed through an ion exchange process. The functional layer may include a first part in the first area and including a first ion, and a second part in the second area and including a second ion having an ion radius greater than an ion radius of the first ion (see FIGS. 5, 6, and 7). In another embodiment, the functional layer may include a first part in the first area and including a first ion by a first amount, and a second part in the second area and including the first ion by a second amount greater than the first amount (see FIGS. 13 and 14).

Accordingly, the strength of the functional layer of the cover window may be increased, and damage caused by bending of the cover window may be prevented.

In the method for manufacturing cover window according to the embodiments of the disclosure, after simultaneously applying different coating solutions (e.g., coating solutions including different types of ions, coating solutions including the same types of ions in different ratios, or the like) to the first area having flexibility on a base member including a glass substrate and the second area positioned adjacent to the first area, ion exchange may be simultaneously performed in the first and second areas by heating the base member to which the coating solutions are applied. Accordingly, the manufacturing process of the cover window may be simplified.

The disclosure may be applied to various display devices. For example, the disclosure is applicable to various display devices such as display devices for vehicles, ships and aircraft, portable communication devices, display devices for exhibition or information transmission, medical display devices, and the like.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A cover window comprising:
a first area and a second area disposed adjacent to the first area;
a base layer disposed in the first area and the second area and having flexibility in the first area; and
a functional layer disposed on at least one surface of the base layer and including:
a first part disposed in the first area and including a first ion; and
a second part disposed in the second area and including a second ion different from the first ion.

2. The cover window of claim 1, wherein an ionic radius of the second ion is greater than an ionic radius of the first ion.

3. The cover window of claim 1, wherein
the first part includes a first amount of the first ion, and
the second part includes the first amount of the second ion.

4. The cover window of claim 1, wherein
the first part includes a first amount of the first ion,
the second part includes a second amount of the second ion, and
the second amount is greater than the first amount.

5. The cover window of claim 1, wherein
the first part has a first thickness in a thickness direction of the base layer, and
the second part has a second thickness greater than the first thickness in the thickness direction.

6. The cover window of claim 1, wherein
a first compressive stress is formed in the first part,
a second compressive stress is formed in the second part, and
a maximum value of the second compressive stress is greater than a maximum value of the first compressive stress.

7. The cover window of claim 1, wherein a same tensile stress is formed in the first area and the second area of the base layer.

8. The cover window of claim 1, wherein a groove is formed on an upper surface of the cover window in the first area.

9. The cover window of claim 1, wherein the cover window includes amorphous glass in the first area and crystalline glass in the second area.

10. The cover window of claim 1, wherein the functional layer includes:
a first functional layer disposed on a first surface of the base layer; and
a second functional layer disposed on a second surface opposite to the first surface of the base layer.

11. A method for manufacturing a cover window, the method comprising:
forming a base member including a glass substrate;
applying a first coating solution including a first ion to at least one surface of the base member in a first area, the first area of the base member having flexibility;
applying a second coating solution including a second ion different from the first ion to the at least one surface of the base member in a second area disposed adjacent to the first area;
heating the base member on which the first and second coating solutions are formed; and
removing the first and second coating solutions.

12. The method of claim 11, wherein
the first coating solution has a first thickness in a thickness direction of the base member, and
the second coating solution has the first thickness in the thickness direction.

13. The method of claim 11, wherein
the base member further includes the second ion,
the first coating solution further includes the second ion, and
the second coating solution further includes the first ion.

14. The method of claim 13, wherein
a ratio of the first ion and the second ion in the first coating solution and a ratio of the first ion and the second ion in the second coating solution are different,
the first coating solution includes a first amount of the first ion,
the second coating solution includes a second amount of the first ion, and
the second amount is greater than the first amount.

15. The method of claim 13, wherein
a ratio of the first ion and the second ion in the first coating solution and a ratio of the first ion and the second ion in the second coating solution are same,
the first coating solution includes a first amount of the first ion,
the second coating solution includes a second amount of the first ion, and
the second amount is greater than the first amount.

16. The method of claim 11, wherein
the base member further includes a third ion different from the first and second ions, and
an ionic radius of the second ion is greater than an ionic radius of the first ion.

17. The method of claim 16, wherein
the first coating solution includes a first amount of the first ion, and
the second coating solution includes the first amount of the second ion.

18. The method of claim 11, wherein the forming of the base member includes:
forming a groove on an upper surface of the base member in the first area; and
crystallizing the glass substrate by heating the second area of the base member.

19. The method of claim 11, wherein
the heating of the base member on which the first and second coating solutions are formed includes forming a cover window including a base layer in the first area and the second area, and a functional layer formed on at least one surface of the base layer, and
the functional layer includes:
a first part disposed in the first area and having a first thickness in a thickness direction of the base member; and
a second part disposed in the second area and having a second thickness greater than the first thickness in the thickness direction.

20. A display device comprising:
a display panel including a display area that displays an image and a non-display area disposed adjacent to the display area; and
a cover window disposed on the display panel and including:
a first area and a second area disposed adjacent to the first area;
a base layer disposed in the first area and the second area and having flexibility in the first area; and
a functional layer disposed on at least one surface of the base layer and including a first part disposed in the first area and including a first ion and a second part disposed in the second area and including a second ion different from the first ion.
